(19) United States
(12) Patent Application Publication
(10) Pub. No.: US 2013/0168683 A1
(43) Pub. Date: Jul. 4, 2013

(54) THIN FILM TRANSISTOR AND MANUFACTURING METHOD THEREOF

(71) Applicants: Mi-Seon SEO, Seoul (KR); Cheol Kyu KIM, Seoul (KR); Sung Hoon YANG, Seoul (KR); Hee Young LEE, Chungju-si (KR); Sang Hyun JEON, Suwon-si (KR)

(72) Inventors: Mi-Seon SEO, Seoul (KR); Cheol Kyu KIM, Seoul (KR); Sung Hoon YANG, Seoul (KR); Hee Young LEE, Chungju-si (KR); Sang Hyun JEON, Suwon-si (KR)

(73) Assignee: SAMSUNG DISPLAY CO., LTD., Yongin-City (KR)

(21) Appl. No.: 13/480,233

(22) Filed: May 24, 2012

(30) Foreign Application Priority Data
Dec. 30, 2011 (KR) 10-2011-0147733

(51) Int. Cl. H01L 29/786; H01L 21/336

(52) U.S. Cl. 257/66; 438/158; 257/E29.273; 257/E21.411

(57) ABSTRACT

A thin film transistor is provided. A thin film transistor according to an exemplary embodiment of the present invention includes: a substrate; a gate electrode disposed on the substrate; a gate insulating layer disposed on the gate electrode; a semiconductor layer disposed on the gate insulating layer; and a source electrode and a drain electrode disposed on a portion of the semiconductor layer, wherein the semiconductor layer includes an ohmic contact layer, a channel layer, and a buffer layer, the buffer layer disposed between the channel layer and the ohmic contact layer, and the source electrode and the drain electrode contact a surface of the ohmic contact layer.

### CROSS-REFERENCE TO RELATED APPLICATION

This application claims priority to and the benefit of Korean Patent Application No. 10-2011-0147733 filed on Dec. 30, 2011, the entire contents of which are incorporated herein by reference.

### BACKGROUND

1. Field

The following description relates to a thin film transistor and a manufacturing method thereof.

2. Discussion of the Background

A thin film transistor may be used as a switching element in a display device, such as a liquid crystal display and an organic light emitting device. A low temperature polysilicon (LTPS) thin film transistor using a top gate structure may have a higher charge mobility than an amorphous silicon thin film transistor using a bottom gate structure. However, if the top gate structure is used, the manufacturing process may be more complicated and a light leakage may be generated due to a leaking current.

More specifically, in the bottom gate structure, light flowing in from an underlying backlight may be blocked to reduce a likelihood of leaking current or light. However, in the top gate structure, the light from an underlying backlight may flow or leak into the channel portion to generate the light leakage or current leakage.

The above information disclosed in this Background section is only for enhancement of understanding of the background of the invention and therefore it may contain information that does not form the prior art that is already known in this country to a person of ordinary skill in the art.

### SUMMARY

Exemplary embodiments of the present invention provide a thin film transistor and a manufacturing method for reducing current leakage.

Additional features of the invention will be set forth in the description which follows, and in part will be apparent from the description, or may be learned by practice of the invention.

Exemplary embodiments of the present invention provide a thin film transistor including a substrate; a gate electrode disposed on the substrate; a gate insulating layer disposed on the gate electrode; a semiconductor layer disposed on the gate insulating layer; and a source electrode and a drain electrode disposed on a portion of the semiconductor layer, wherein the is semiconductor layer includes an ohmic contact layer, a channel layer, and a buffer layer, the buffer layer disposed between the channel layer and the ohmic contact layer, and the source electrode and the drain electrode contact a surface of the ohmic contact layer.

Exemplary embodiments of the present invention provide a method for manufacturing a thin film transistor including forming a gate electrode on a substrate; forming a gate insulating layer on the gate electrode; forming a semiconductor material layer on the gate insulating layer; forming a first photosensitive film pattern on the semiconductor material layer, in which the first photosensitive film pattern includes a first region and a second region, and the second region is thinner than the first region; patterning the semiconductor material layer by using the first photosensitive film pattern as a mask to form a semiconductor layer; injecting a first impurity to an edge portion of the semiconductor layer through the second region of the first photosensitive film pattern to form an ohmic contact layer; ashing the first photosensitive film pattern to form a second photosensitive film pattern; injecting a second impurity to the semiconductor layer by using the second photosensitive film pattern as a mask to form a buffer layer; and forming a source electrode and a drain electrode on the ohmic contact layer.

Exemplary embodiments of the present invention provide a method for manufacturing a thin film transistor including forming a gate electrode on a substrate; forming a gate insulating layer on the gate electrode; forming a semiconductor material layer on the gate insulating layer; forming a first photosensitive film pattern including a first region and a second region on the semiconductor material layer, the second region being thinner than the first region; patterning the semiconductor material layer by using the first photosensitive film pattern to form a semiconductor layer, the semiconductor layer including a first portion, a second portion and a third portion; injecting a first impurity to the first portion of the semiconductor layer through the is second region of the first photosensitive film pattern to form an ohmic contact layer; ashing the first photosensitive film pattern to form a second photosensitive film pattern, in which the second photosensitive film pattern exposes the second portion of the semiconductor layer and masks the third portion of the semiconductor layer; injecting a second impurity to the second portion of the semiconductor layer using the second photosensitive film pattern as a mask to form a buffer layer; and forming a source electrode and a drain electrode to contact the ohmic contact layer.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a thin film transistor according to an exemplary embodiment of the present invention.

FIG. 2, FIG. 3, FIG. 4, FIG. 5, FIG. 6, FIG. 7, FIG. 8 and FIG. 9 are cross-sectional views illustrating a manufacturing method for a thin film transistor according to an exemplary embodiment of the present invention.

### DETAILED DESCRIPTION OF THE ILLUSTRATED EMBODIMENTS

The present invention will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. Throughout the drawings and the detailed description, unless otherwise described, the same drawing reference numerals are understood to refer to the same elements, features, and structures. The relative size and depiction of these elements may be exaggerated for clarity.

It will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ).

It will be understood that if an element, such as a layer, film, region, or substrate, is referred to as being “on” another element, it can be directly on the other element or intervening elements may also be present.

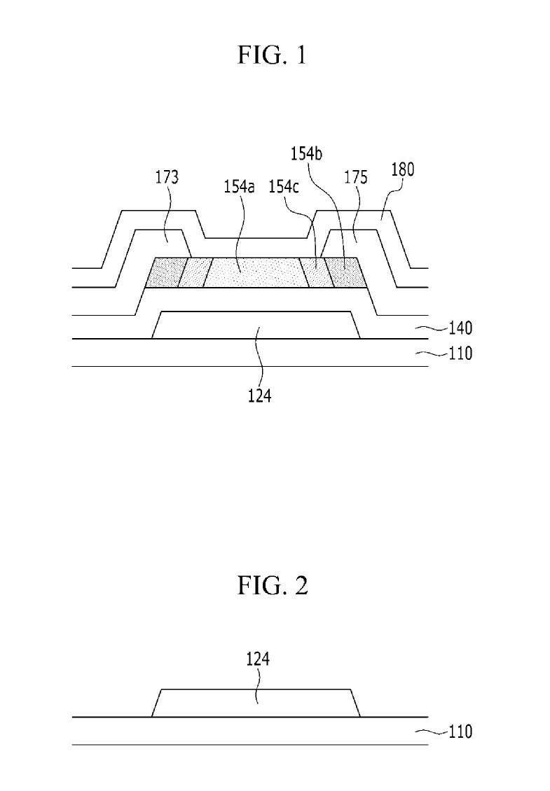

FIG. 1 is a cross-sectional view of a thin film transistor according to an exemplary embodiment of the present invention.

Referring to FIG. 1, a gate electrode 124 is disposed on an insulation substrate 110. The insulation substrate 110 may be made of a transparent glass, plastic, or the like.

The gate electrode 124 may include, without limitation, an aluminum-based metal, such as aluminum (Al) and aluminum alloys, a silver-based metal, such as silver (Ag) and silver alloys, or a copper-based metal, such as copper (Cu) and copper alloys.

The gate electrode 124 may have a single layer composition, however, it is not limited thereto, and may have a dual layer or a triple layer composition.

In a case of the dual-layer structure, the gate electrode 124 may include a lower layer and an upper layer. The lower layer may include, without limitation, a material selected from a molybdenum-based metal, such as molybdenum (Mo) and molybdenum alloys, a chromium-based metal, such as chromium (Cr) and chromium alloys, a titanium-based metal, such as titanium (Ti) and titanium alloys, a tantalum-based metal, such as tantalum (Ta) and tantalum alloys, and a manganese-based metal, such as manganese (Mn) and manganese alloys. The upper layer may include, without limitation, a material selected from an aluminum-based metal, such as aluminum (Al) and aluminum alloys, a silver-based metal, such as silver (Ag) and silver alloys, and a copper-based metal, such as copper (Cu) and copper alloys. In the triple layer structure, different layers having different physical properties may be combined.

A gate insulating layer 140 covering the gate electrode 124 is formed on the gate electrode 124. The gate insulating layer 140 may include silicon nitride (SiNx) or silicon oxide (SiOx).

A semiconductor layer is disposed the gate insulating layer 140. The semiconductor layer includes a channel layer 154a, two ohmic contact layers 154b, and two buffer layers 154c. The channel layer 154a corresponds to a central portion of the gate electrode 124. The ohmic contact layers 154b are disposed at outer edges of the semiconductor layer, next to the buffer layers 154c. Each buffer layer 154c is disposed between the channel layer 154a and one of the ohmic contact layers 154b.

The channel layer 154a, the ohmic contact layers 154b, and the buffer layers 154c are disposed in the same layer.

The ohmic contact layers 154b and the buffer layers 154c may be doped with an n+ impurity or a p+ impurity, and the impurity doping concentration of the buffer layer 154c is may be lower than the impurity doping concentration of the ohmic contact layer 154b.

A source electrode 173 and a drain electrode 175 are disposed on the ohmic contact layer 154b. More specifically, the ohmic contact layer 154b may be partitioned into two portions corresponding to the outer portions of the semiconductor layer with respect to the channel layer 154a. Further, the source electrode 173 and the drain electrode 175 may be disposed on a portion of the semiconductor layer to contact upper and lateral surfaces of each ohmic contact layer 154b. Alternatively, the source electrode 173 and the drain electrode 175 may not contact the upper surface of the ohmic contact layer 154b, but may contact the lateral surface of the ohmic contact layer 154b, or vice-versa. The source electrode 173 and the drain electrode 175 may cover the upper surface of the gate insulating layer 140.

The source electrode 173 and the drain electrode 175 may include, without limitation, a material selected from an aluminum-based metal, such as aluminum (Al) and aluminum alloys, a silver-based metal, such as silver (Ag) and silver alloys, and a copper-based metal, such as copper (Cu) and copper alloys.

The source electrode 173 and drain electrode 175 may have a single layer composition, however, they are not limited thereto, and may have a dual layer composition or a triple layer composition.

In the case of the dual-layer structure or composition, the data line 171, the source electrode 173, and the drain electrode 175 may include a lower layer and an upper layer. The lower layer may include, without limitation, a material selected from a molybdenum-based metal, such as molybdenum (Mo) and molybdenum alloys, a chromium-based metal, such as chromium (Cr) and chromium alloys, a titanium-based metal, such as titanium (Ti) and titanium alloys, a tantalum-based metal, such as tantalum (Ta) and tantalum alloys, and a manganese-based metal, such as manganese (Mn) and manganese alloys. The upper layer may include, without limitation, a material selected from an aluminum-based metal, such as aluminum (Al) and aluminum alloys, a silver-based metal, such as silver (Ag) and silver alloys, and a copper-based metal, such as copper (Cu) and copper alloys. In the triple layer structure, different layers having different physical properties may be combined.

A passivation layer 180 is disposed on the source electrode 173, the drain electrode 175, and the channel layer 154a. The passivation layer 180 may be made of an inorganic insulator or an organic insulator and may have a flat surface portion. The organic insulator may have a dielectric constant of less than 4.0, and photosensitivity.

The ohmic contact layer 154b and the buffer layer 154c may have a symmetrical structure with respect to the channel layer 154a.

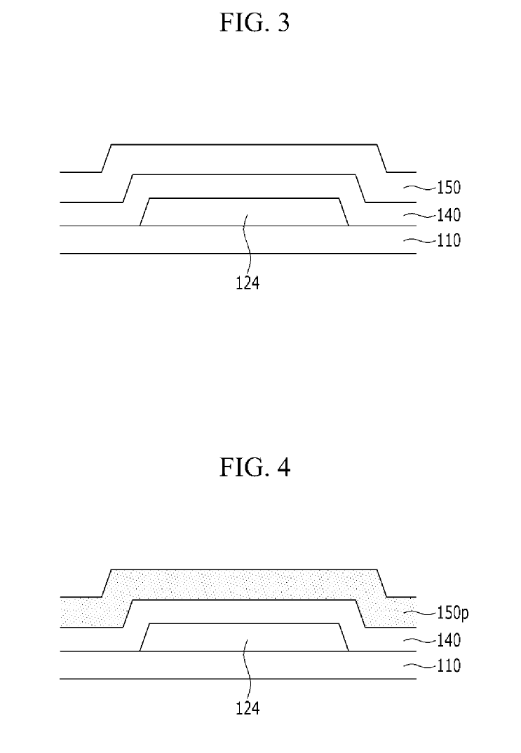

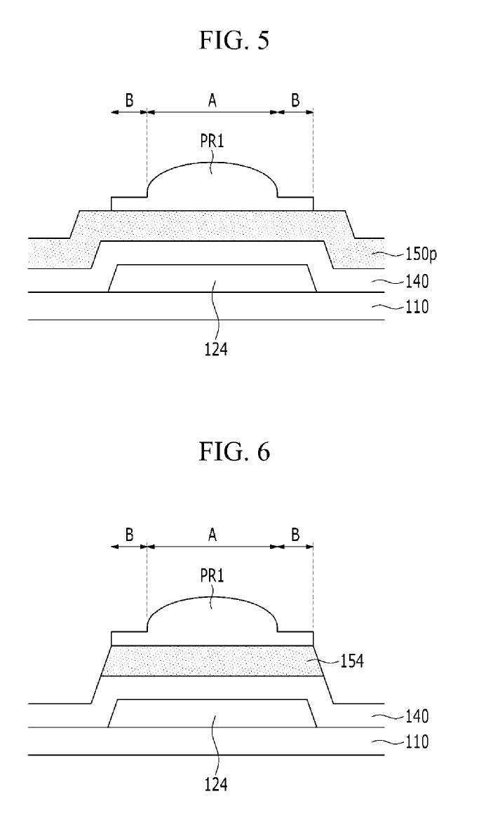

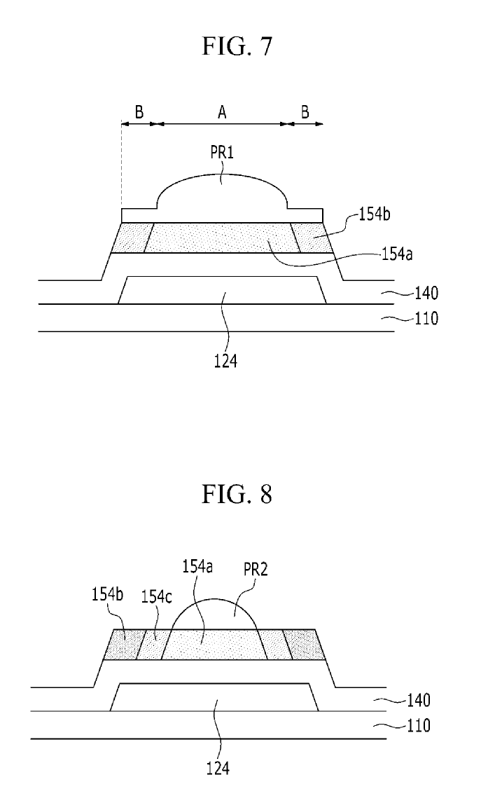

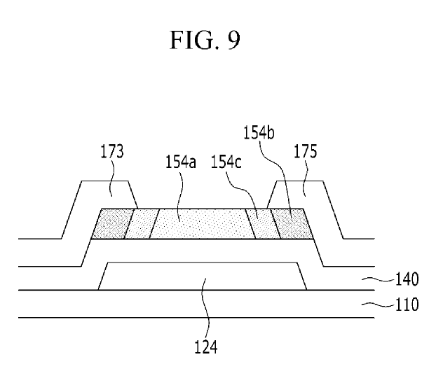

FIG. 2, FIG. 3, FIG. 4, FIG. 5, FIG. 6, FIG. 7, FIG. 8 and FIG. 9 are cross-sectional views illustrating a manufacturing method for a thin film transistor according to an exemplary embodiment of the present invention.

Referring to FIG. 2, a gate electrode 124 is formed on an insulation substrate 110, which may be made of transparent glass or plastic. The gate electrode 124 may be formed by depositing and patterning a metal material disposed on the insulation substrate 110 through a photolithography or other similar process. The metal material may include, without limitation, a material selected from a aluminum-based metal, such as aluminum (Al) and aluminum alloys, a silver-based metal, such as silver (Ag) and silver alloys, and a copper-based metal, such as copper (Cu) and copper alloys.

Referring to FIG. 3, a gate insulating layer 140 covering the gate electrode 124 and an amorphous silicon layer 150 disposed over the gate insulating layer 140 are sequentially is formed on the insulation substrate 110. For example, the gate insulating layer 140 and the amorphous silicon layer 150 may be deposited by using chemical vapor deposition (CVD).

Referring to FIG. 4, the amorphous silicon layer 150 of FIG. 3 may be crystallized by a laser crystallization method or a thermal crystallization method to form a polycrystalline silicon layer 150p. Further, the amorphous silicon layer 150 of FIG. 3 may be crystallized by an annealing process.

The crystalline silicon layer 150p may be processed at a temperature of less than 600 degrees to be made as a low temperature polycrystalline silicon layer, such that deformation of the material forming the insulation substrate 110, such as glass or plastic, may not be generated.

Referring to FIG. 5, a photosensitive material is coated on the polycrystalline silicon layer 150p and pattered to form a first photosensitive film pattern PR1. The first photosensitive film pattern PR1 includes a first region A corresponding to the central portion of the gate electrode 124 and a second region B disposed at the edges of the first region A and having a different thickness from the first region A. That is, the second region B may be thinner than the first region A. To form the different thicknesses of the first photosensitive film pattern PR1 in the first region A and the second region B, a halftone exposure method or a slit exposure method may be used.

Referring to FIG. 6, the polycrystalline silicon layer 150p is etched by using the first photosensitive film pattern PR1 as a mask. At this time, the patterned semiconductor layer 154 is formed from the polycrystalline silicon layer 150p. The semiconductor layer 154 overlaps the gate electrode 124.

Referring to FIG. 7, the first impurity is injected through the first photosensitive is film pattern PR1 of the second region B, which may be thinner than the first region A, to form an ohmic contact layer 154b at the edges of the semiconductor layer 154. The ohmic contact layer 154b may decrease contact resistance between source electrodes and drain electrodes that may be formed later, and the semiconductor layer 154. By controlling the thickness of the first photosensitive film pattern PR1 disposed at the second region B, the doping concentration of the ohmic contact layer 154b may be controlled.

Referring to FIG. 8, the first photosensitive film pattern PR1 may be process further using, for example an ashing operation using O2 gas. At this time, the thickness of a horizontal direction of the first photosensitive film pattern PR1 is reduced as well as the thickness of a vertical direction, thereby masking the central portion of the channel layer 154a, but exposing portions of the semiconductor layer, which will later be formed as buffer layers 154c. The second photosensitive film pattern PR2 covering a portion of the upper surface of the channel layer 154a is formed while reducing the width of the first photosensitive film pattern PR1 by the ashing.

The channel layer 154a is formed at the masked portion of the semiconductor layer corresponding to the second photosensitive film pattern PR2, and the ohmic contact layer 154b and the buffer layer 154c may have a symmetrical structure with respect to the channel layer 154a.

Here, the second impurity is injected to the semiconductor layer 154 by using the second photosensitive film pattern PR2 as an impurity ion injection mask to form buffer layers 154c, which is located between the ohmic contact layers 154b and the channel layer 154a. The second impurity may have a lower doping concentration than the injected first impurity. In other words, the buffer layer 154c becomes a lightly doped drain (LDD) region.

In the thin film transistor according exemplary embodiments of the present invention, one exposure process may be executed while forming the semiconductor layer 154, which may include the channel layer 154a, the ohmic contact layer 154b, and the buffer layer 154c, by using the first photosensitive film pattern PR1 and the second photosensitive film pattern PR2.

Referring to FIG. 9, the second photosensitive film pattern PR2 may be removed through a stripping operation by using a material, such as acetone, to form a source electrode 173 and a drain electrode 175 contacting the ohmic contact layer 154b.

The source electrode 173 and the drain electrode 175 may be formed by depositing a material selected from at least one of a aluminum-based metal, such as aluminum (Al) and aluminum alloys, a silver-based metal, such as silver (Ag) and silver alloys, and a copper-based metal, such as copper (Cu) and copper alloys. The source electrode 173 and the drain electrode 175 may be formed on the semiconductor layer 154 and the gate insulating layer 140, which may be patterned through the photolithography process.

The source electrode 173 and the drain electrode 175 are formed to contact the upper surface and the lateral surface of the ohmic contact layer 154b. However, the source electrode 173 and the drain electrode 175 may not contact both the upper surfaces and the lateral surfaces of the of the ohmic contact layer 154b. For example, the source electrode 173 and the drain electrode 175 may not contact the upper surface of the ohmic contact layer 154b, but may maintain contact with the lateral surfaces of the ohmic contact layer 154b and vice-versa.

Next, a passivation layer 180 may be formed over the source electrode 173, the drain electrode 175, and the semiconductor layer 154 to form the thin film transistor of FIG. 1.

According to exemplary embodiments of the present invention, in the bottom gate structure, the buffer layer corresponding to the LDD region may be formed such that off current or current leakage may be reduced. Also, if forming the buffer layer, the ashing process may be performed without a photoprocess such that an alignment issue that may be generated associated with the photoprocess may be resolved, and the number of masks may be reduced, such that the manufactured cost may be reduced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor, comprising:
a substrate;
a gate electrode disposed on the substrate;
a gate insulating layer disposed on the gate electrode;
a semiconductor layer disposed on the gate insulating layer; and
a source electrode and a drain electrode disposed on a portion of the semiconductor layer,
wherein the semiconductor layer comprises an ohmic contact layer, a channel layer, and a buffer layer,
the buffer layer disposed between the channel layer and the ohmic contact layer, and
the source electrode and the drain electrode contact a surface of the ohmic contact layer.

2. The thin film transistor of claim 1, wherein
the semiconductor layer comprises polycrystalline silicon.

3. The thin film transistor of claim 1, wherein
the ohmic contact layer and the buffer layer are doped with an impurity, the impurity concentration of the buffer layer being lower than the impurity concentration of the ohmic contact layer.

4. The thin film transistor of claim 1, further comprising
a passivation layer disposed on the source electrode, the drain electrode, and the semiconductor layer.

5. The thin film transistor of claim 4, wherein
the passivation layer contacts a surface of the buffer layer.

6. The thin film transistor of claim 1, wherein
the ohmic contact layer, the channel layer, and the buffer layer are disposed in the same layer.

7. The thin film transistor of claim 1, wherein
the ohmic contact layer, the channel layer, and the buffer layer are disposed directly on the same layer.

8. The thin film transistor of claim 7, wherein
the ohmic contact layer, the channel layer, and the buffer layer are disposed directly on the gate insulating layer.

9. The thin film transistor of claim 1, wherein
the source electrode and the drain electrode contact the surface of the ohmic contact layer.

10. The thin film transistor of claim 1, wherein
the channel layer is disposed at a central region of the semiconductor layer, and the ohmic contact layer and the buffer layer have a symmetrical structure with respect to the channel layer.

11. A method for manufacturing a thin film transistor, comprising:
forming a gate electrode on a substrate;
forming a gate insulating layer on the gate electrode;
forming a semiconductor material layer on the gate insulating layer;
forming a first photosensitive film pattern on the semiconductor material layer, wherein the first photosensitive film pattern comprises a first region and a second region, and the second region is a thinner than the first region;
patterning the semiconductor material layer by using the first photosensitive film pattern as a mask to form a semiconductor layer;
injecting a first impurity to an edge portion of the semiconductor layer through the second region of the first photosensitive film pattern to form an ohmic contact layer;
ashing the first photosensitive film pattern to form a second photosensitive film pattern;
injecting a second impurity to the semiconductor layer by using the second photosensitive film pattern as a mask to form a buffer layer; and
forming a source electrode and a drain electrode on the ohmic contact layer.

12. The method of claim 11, wherein
the buffer layer is formed between a channel layer and the ohmic contact layer.

13. The method of claim 12, wherein
the second impurity has a lower doping concentration than the first impurity.

14. The method of claim 13, wherein
the ohmic contact layer, the buffer layer, and the channel region are formed on the same layer.

15. The method of claim 14, wherein
the ashing of the first photosensitive film pattern to form the second photosensitive film pattern comprises reducing the width of the first photosensitive film pattern for exposing a portion of the polycrystalline silicon semiconductor layer corresponding to the first region of the first photosensitive film.

16. The method of claim 15, further comprising
forming a passivation layer on the source electrode, the drain electrode, and the semiconductor layer.

17. The method of claim 16, wherein
the passivation layer contacts the surface of the buffer layer.

18. The method of claim 11, wherein
the forming of the semiconductor material layer comprises:
forming an amorphous silicon layer on the gate insulating layer, and
crystallizing the amorphous silicon layer to form a polycrystalline silicon layer.

19. The method of claim 11, wherein
the first photosensitive film pattern and the second photosensitive film pattern are formed through one exposure process.

20. The method of claim 19, wherein
the forming of the first photosensitive film pattern comprises using a halftone exposure method or a slit exposure method.

21. The method of claim 11, wherein
the source electrode and the drain electrode contact a surface of the ohmic contact layer.

22. The method of claim 11, further comprising
removing the second photosensitive film pattern before forming the source electrode and the drain electrode.

23. A method for manufacturing a thin film transistor, comprising:
forming a gate electrode on a substrate;
forming a gate insulating layer on the gate electrode;
forming a semiconductor material layer on the gate insulating layer;
forming a first photosensitive film pattern comprising a first region and a second region on the semiconductor material layer, the second region being thinner than the first region;
patterning the semiconductor material layer by using the first photosensitive film pattern to form a semiconductor layer, the semiconductor layer comprising a first portion, a second portion and a third portion;
injecting a first impurity to the first portion of the semiconductor layer through the second region of the first photosensitive film pattern to form an ohmic contact layer;
ashing the first photosensitive film pattern to form a second photosensitive film pattern, wherein the second photosensitive film pattern exposes the second portion of the semiconductor layer and masks the third portion of the semiconductor layer;
injecting a second impurity to the second portion of the semiconductor layer using the second photosensitive film pattern as a mask to form a buffer layer; and
forming a source electrode and a drain electrode to contact the ohmic contact layer.
